(19) United States
(12) Patent Application Publication
(10) Pub. No.: US 2007/0090861 A1
(43) Pub. Date: Apr. 26, 2007

(54) Optical flip-flop based read-out arrangement

(75) Inventors: Ole Klembt Andersen, Eindhoven (NL); Coen Theodorus Hubertus Fransiscus Liedenbaum, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONIC, N.V., EINDHOVEN (NL)

(21) Appl. No.: 10/596,643

(22) PCT Filed: Dec. 13, 2004
(86) PCT No.: PCT/IB04/04184

§ 371 Date: Jun. 20, 2006

(30) Foreign Application Priority Data
Dec. 23, 2003 (EP) 03300287.4

(51) Int. Cl. H03B 19/08

(52) U.S. Cl. 327/123

(57) ABSTRACT

An arrangement for read-out of information stored on an optical information carrier (30) is disclosed. Light from a master laser (10) is reflected from the information carrier (30) and injected into a slave laser (20) in polarization state that is generally orthogonal to the free-running polarization of the slave laser. The amount of injected light required to switch the polarization of the slave laser depends upon the wavelength difference between the master laser and the free-running slave laser. By controlling the wavelength difference between the two lasers, the arrangement is capable of reading different gray-levels from the information carrier (30).

### TECHNICAL FIELD

The present invention relates to an arrangement for optical read-out of information stored on an optical information carrier. The invention also relates to an optical drive comprising such read-out arrangement, and to a method of reading information from an optical information carrier.

### BACKGROUND OF THE INVENTION

Optical data storage is becoming increasingly popular and much of the current development aims at storing larger amounts of data on storage means of equal or less size than previously. One way of storing more data without increasing the storage area is to use shorter wavelengths for the light used for writing and reading. Other ways of increasing the storage density is to use multi-level storage. In multi-level storage, information is recorded in the form of marks giving rise to a number of different reflectivities, i.e. more than one bit of information is stored in each mark on the storage means. In this way, more information can be recorded without enlargin the storage area.

When using multi-level storage, the read-out of information must be handled in a different way than in the prior art single-level recording techniques.

U.S. Pat. No. 5,854,779 discloses a method of reading multi-level data from an optical disc, the method being based on elaborate signal processing including dynamic calibration of signal values.

However, there is a general need in the art for improved schemes for read-out of information from optical information carriers.

### SUMMARY OF THE INVENTION

The present invention aims at providing a novel arrangement for read-out of information from a multi-level data storage medium.

Diode lasers are an essential part of optical storage applications. In the near future, it is expected that dual-stripe diode lasers in the wavelength region at about 405 nm will become available. Dual-stripe diode lasers comprise a high-power laser and a low-power laser in the same mount separated by a few hundred microns.

By virtue of their open cavity (i.e. a cavity with low-reflectivity facets), high-power diode lasers are well suited for injection of light from another laser, for example from the low-power laser of the same dual-stripe laser. By injection of this kind, the high-power laser can, for example, be forced to emit the same wavelength as the injected wavelength (wavelength locking), or the polarization of the emitted light can be changed to the polarization mode of the injected light (polarization locking). In a dual-stripe laser as mentioned above, this means that the low-power laser can be employed in order to lock the high-power laser to the wavelength and/or polarization of the low-power laser.

For example, this principle can be used in order to provide an optical flip-flop. The principle behind the optical flip-flop is based on polarization switching.

The present invention provides an arrangement according to claim 1 for read-out of information stored on an optical disc that enables the read-out of multi-level optical data storage. The inventive arrangement is based on an optical flip-flop.

The inventive arrangement can be used also for conventional single-level data storage, and then gives significant improvements over the prior art, as will be further described below.

The invention also provides a method of reading information from an optical information carrier according to claim 6, and an optical drive according to claim 8.

The optical drive provided with the arrangement according to the present invention thus has several advantages, as will be further explained below.

Among the general advantages of the present invention, may be mentioned a reduced sensitivity to media noise, increased robustness in terms of compatibility between different media formats, and increased signal-to-noise ratio in the read-out signal.

The present invention is based on the use of an optical flip-flop for reading information from an optical information carrier. To this end, light from a master laser is reflected from the information carrier and then injected into a slave laser. When a sufficient amount of light from the master laser is injected into the slave laser, the state of the slave laser will become locked to that of the injected light. Generally, the injected light can be regarded as giving rise to an increased gain in the slave laser.

The invention is based on the idea of controlling the wavelength of the injected light in order to select the sensitivity of the slave laser to this injection. A larger wavelength difference between the injected light and the free-running wavelength of the slave laser leads to a lower sensitivity to injection locking, and vice versa. This fact is the basis for resolving different gray-levels from the information carrier.

### BRIEF DESCRIPTION OF THE DRAWINGS

The features and advantages of the invention will be further elucidated by the following detailed description, which will be given with reference to the accompanying drawings, on which:

FIG. 1 schematically shows a typical set-up for an optical flip-flop according to the present invention;

FIG. 2 is a graph showing the bi-stable nature of the optical flip-flop; and

FIG. 3 illustrates the read-out of a multi-level recording using an optical flip-flop according to the present invention.

### DETAILED DESCRIPTION OF EMBODIMENTS

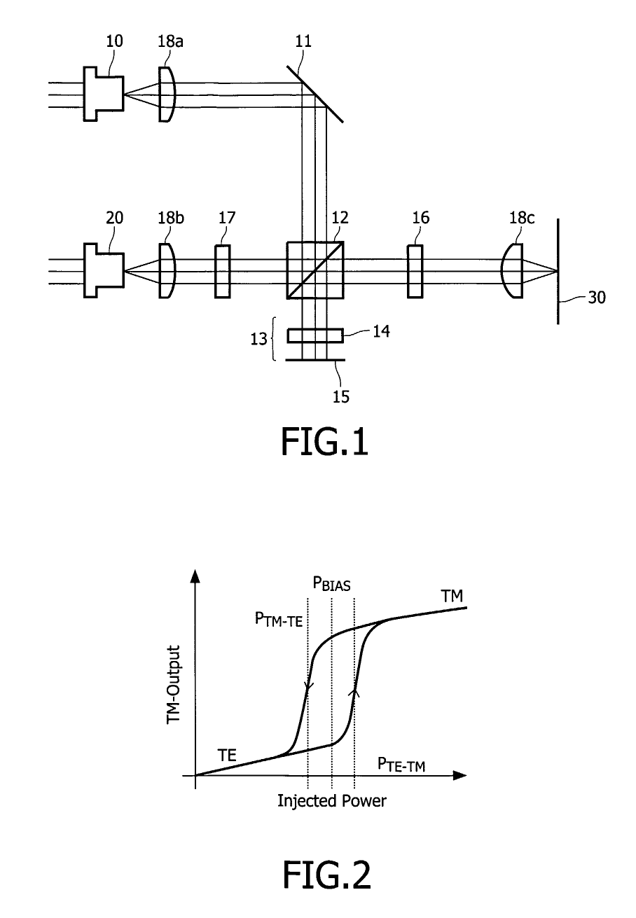

Optical flip-flops can be implemented in various ways. The example presented here and schematically shown in FIG. 1 includes the injection of light from a master laser into a slave laser for locking the slave laser to a certain polarization mode. The state of the flip-flop is controlled by the amount of light injected into the slave laser and by the wavelength difference between the master laser and the slave laser.

By way of introduction, the principle behind this optical flip-flop will be described with reference to FIG. 1.

A low-power laser 10 constitutes the master laser, and a high-power laser 20 is the slave laser. Suitably, these lasers could be the two lasers of a dual-stripe laser package. The master laser 10 is stabilized using feedback from a grating 11. The orientation of the grating 11 determines the emission wavelength of the master laser 10 by feedback of the desired operating wavelength into the master laser 10.

The aim is now to inject light from the master laser 10 into the slave laser 20 at a polarization that is normal to a free-runming polarization of the slave laser. In this specification, the term “free-running” means the state of the laser without injection. Above a certain power for the injected light, the injection from the master laser 10 will have the effect of locking the slave laser 20 to the polarization and the wavelength of the injected light, i.e. the slave laser will toggle to another polarization state. The operation of the optical flip-flop is the toggling between polarization states of the slave laser 20 depending on the amount of injected light and its wavelength.

To toggle the optical flip-flop, the light from the master laser 10 is reflected from a surface of varying reflectivity. In an actual implementation, this surface will of course be the optical recording medium or storage means 30.

More specifically, in order for light from the master laser to be reflected off the variable-reflection surface 30 and then injected into the slave laser 20 at the appropriate polarization, a combination of wave-plates and a polarizing beam-splitter 12 is used. Light from the master laser 10 is passed through the polarizing beam-splitter 12 (PBS) and then along a polarization-rotating branch 13. Rotation of the polarization is obtained by sending the light through a quarter wave-plate 14 (λ/4-plate), which is oriented in such a sense that the polarization of the light is circularly polarized after one passage. The circularly polarized light is then reflected from a plane mirror 15 back towards said PBS 12, whereby the polarization is transformed from circular into a linear polarization rotated by 90° from the original polarization after the second passing of the wave-plate 14. Since the polarization of the light has been rotated by 90°, the PBS 12 now has the effect of reflecting the light towards the variable-reflection surface 30 (the optical storage disc). Before reaching this reflection surface, the light passes another quarter-wave-plate 16 to attain circular polarization. After having been reflected from the storage medium 30, the light again passes the second quarter-wave-plate 16, giving a polarization that is rotated by 90° with respect to the incident light, such that the light will now pass through the PBS 12 towards the slave laser 20. Before being injected into the slave laser, the light passes a half-wave-plate 17 (λ/2-plate) in order for the polarization to be rotated by 90° such that it is normal to the free-running polarization of the slave laser 20. Depending on the orientation of the lasers, the λ/2-plate may be omitted in some embodiments, as will be appreciated by those skilled in the art. Lenses 18a-c are provided for focusing/collimating the light.

The free-running slave laser 20, i.e. without injection, operates in a transverse electric mode (TE-mode), with the electric field vector parallel to the junction of the laser. The injection from the master laser 10 corresponds to injecting a transverse magnetic mode (TM-mode) into the slave laser, with the electric field vector of the injected light normal to the junction of the slave laser. When the power of the injected TM-mode light from the master laser 10 exceeds a certain level, the polarization mode of the slave laser 20 changes from transverse electric (TE) to transverse magnetic (TM), i.e. the polarization of the slave laser is locked to that of the injected light. In most actual situations, the slave laser is pulsed by modulation of the driving current, and just below the lasing threshold the slave laser is very sensitive to injection from the master laser.

Switching of the polarization state from the TE-mode to the TM-mode in the slave laser 20 occurs as soon as the gain of the TM-mode exceeds the gain of the TE-mode. Similarly, switching back from the TM-mode to the TE-mode occurs when the gain of the TE-mode exceeds the gain of the TM-mode. As a result of the injection of the TM-polarized light, the gain of the TM-mode in the slave laser is increased and eventually exceeds the gain of the TE-mode.

The existence of a polarization bi-stability in an injected laser diode has previously been reported (Y. Mori, et al., “High switching-speed optical RS flip-flop constructed of a TM-wave injected semiconductor laser” in Int. Electron. Devices Meeting, Technical Digest, 610-613, Los Angeles 1986). When the injection level exceeds a certain value, P_{TE-TM}, the polarization mode of the slave laser changes from TE to TM. Lowering the injection level below another value, P_{TM-TE}, returns the state of the slave laser from TM to TE. Since the second level P_{TM-TE} is generally lower than the first level P_{TE-TM}, the system is bi-stable. This is schematically illustrated in FIG. 2, showing the output in the TM-mode as a function of the injected power. This bi-stability is the basis for the optical flip-flop.

The state of the optical flip-flop can be determined by monitoring the output polarization from the slave laser. In addition, if the bias level is selected to be close to the threshold, such that the slave laser has laser action in the TM-state, but does not lase when it is in the TE-state, a monitoring photodiode (MPD) typically integrated in the diode package can be used for detecting the state of the flip-flop. In other words, if the slave laser is lasing the flip-flop is in a first state (TM-state), and if it is not lasing it is in the second state (TE-state). Hence, sufficient injection is required for the slave laser to reach lasing.

During read-out of information stored on the optical disc 30 (in the form of marks or spots of low and high reflection), the information is converted into intensity variations of the TM-polarized light injected into the slave laser 20. As explained above, if the bias level is selected close to the threshold of the slave laser, the integrated MPD in the laser diode package could then be used for bit-detection. The MPD has a large bandwidth (several GHz) and is well suited for detecting whether or not the laser is lasing.

According to the present invention, the idea of using an optical flip-flop for reading information from an optical storage medium is extended to the read-out of information in multi-level optical data storage.

The invention is based on the fact that the injected power required to lock the polarization of the slave laser 20 to the polarization of the master laser 10 depends on the difference in wavelength between the two lasers. The more the wavelength of the master laser 10 deviates from the wavelength of the free-running slave laser 20, the more light (higher power) must be injected to achieve locking. Referring back to the description above, this means that when the wavelength difference between the two lasers is increased, the transition levels P_{TE-TM} and P_{TM-TE} moves towards higher injection levels (to the right in FIG. 2).

The wavelength difference between the master laser and the free-running slave laser is determined by the orientation of the grating 11 used for stabilizing and selecting the output wavelength for the master laser 10. Now, by employing the above-described phenomenon, polarization-mode switching in an optical flip-flop can be realized that is dependent upon the wavelength difference between the two lasers. A smaller difference in wavelength leads to a more sensitive read-out of the stored information (less reflection from the information carrier is required to achieve locking of the slave laser). This can then be employed for resolving gray-levels in the stored information.

A major advantage of using an optical flip-flop for read-out is a reduced sensitivity to media noise. As described in this specification, bits are detected when the reflected light from the storage means 30 crosses a certain threshold value. This has the consequence that reflectivity variations inherent in the storage means 30 do not have any effect as long as these variations are not so large that the threshold is crossed. This is particularly advantageous in connection with multi-level data storage.

Further, since the detection of bits is reduced to detecting transitions between two states (the states of the optical flip-flop, i.e. polarization states), the slicer typically implemented in prior art disc-drives would be obsolete. The purpose of such a slicer is to detect the DC-level around which the reflected light from the storage means is modulated. This DC-level is not necessarily constant, but may show fluctuations in time. For the optical flip-flop however, the DC-level is constant.

The dynamic range, i.e. the allowed difference in reflectivity between marks and empty regions, depends on the type of storage medium. For example, a read-write disc (RW-disc) has a different dynamic range than read-only discs (ROM-discs). Again, since the detection of information is reduced to the detection of a threshold transition, read-out with an optical flip-flop offers an increased robustness in terms of compatibility.

In contrast to low-power diode lasers, high-power diode lasers operating around 405 nm are known to be fairly noisy. In an implementation of the present invention, the larger noise of the slave laser 20 is likely to be reduced as a consequence of injecting less noisy light from the low-power master laser 10. Detector noise, i.e. the variation in the number of photons reaching the detector, is also not an issue in the case of optical flip-flops due to the fact that information is detected by discriminating between the two states of the flip-flop.

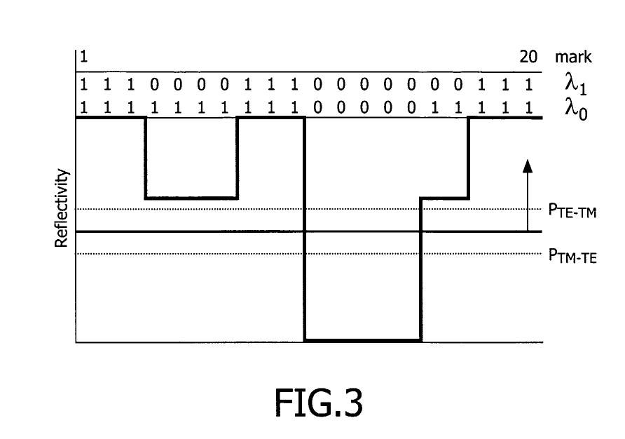

With reference to FIG. 3 of the drawings, the read-out of gray-level bit-patterns from an optical storage means will now be described in more detail.

When the wavelength emitted by the master laser 10 is close to the free-running wavelength of the slave laser 20, a rather low injection level is required in order to switch the polarization mode of the slave laser from transverse electric (TE) to transverse magnetic (TM) (i.e. from its free-running state to its locked state). The amount of light injected into the slave laser 20 is determined by the emitted power of the master laser 10 and by the reflectivity of the marks written on the optical storage means 30. Hence, at a constant output power of the master laser 10, the amount of light required for switching the polarization state is primarily determined by the reflectivity of the marks on the storage means 30. In effect, for a predetermined wavelength difference between the master laser 10 and the free-running slave laser 20, a certain reflectivity is required in order to achieve polarization switching. If the wavelength difference between the master laser 10 and the free-running slave laser 20 is made larger, a higher reflectivity of the information surface 30 is needed in order to achieve switching (assuming the output power of the master laser is held constant). The reason behind this is, as stated above, that injection-locking is a function of both the injected power and of the wavelength difference. Therefore, different gray-levels of the marks on the storage means 30 can be read by controlling the wavelength of the master laser 10, such that a larger wavelength difference is selected when a highly reflecting information structure is read, and a smaller wavelength difference is selected when a less reflecting information structure is read. The wavelength of light emitted by the master laser 10 is suitably controlled by means of the grating 11 which is used for stabilizing this laser. However, any other means for controlling the output wavelength of the master laser 10 could be used.

Now suppose that the storage means 30 has a bit-pattern as indicated in FIG. 3. The figure shows a 20-bit pattern written using gray-levels (thick, solid curve). As mentioned above, increasing the wavelength difference between the master laser 10 and the free-running slave laser 20 results in a shift of the switching levels P_{TE-TM} and P_{TM-TE} towards higher values. Such a shift then corresponds to a situation where a higher reflectivity of the marks on the storage means is required in order to achieve switching of the state of the optical flip-flop (again assuming that the output power of the master laser 10 is kept constant).

The solid curve of FIG. 3 can be regarded as showing the amount of TM-polarized light injected into the slave laser 20. Hence, by controlling the wavelength difference between the master laser 10 and the free-running slave laser 20, it is possible to control whether a certain amount of reflected light should be enough to switch the polarization of the slave laser 20 or not. When the wavelength difference is comparatively small, a small amount of reflected light is sufficient in order to switch the polarization. As the wavelength difference becomes larger, increasing amounts of reflected light are required to achieve switching.

Taking the bit-pattern of FIG. 3 as an example, the storage means has marks of three different reflectivities, resulting in three different light-levels being injected into the slave laser. In the situation shown in FIG. 3, the highest reflectivity (marks 1-3, 8-10, and 18-20) is always interpreted as a binary one, and the lowest reflectivity (marks 11 - 15) is always interpreted as a binary zero. The third, intermediate reflectivity (marks 4-7 and 16-17), however, can be interpreted as either a binary one or a zero, depending on the wavelength difference between the two lasers.

Assume that the output wavelength of the master laser 10 can be set to either λ₀ (smaller wavelength difference) or λ₁ (larger wavelength difference). If the output wavelength of the master laser is set to λ₀ giving the smaller wavelength difference between the master laser and the slave laser, the reflection from these intermediate reflectivity marks is sufficient in order to achieve locking of the slave laser. This is illustrated by the lower of the two bit sequences in FIG. 3. Only the marks of lowest reflectivity result in a reflected (injected) power below P_{TM-TE} such that the slave laser becomes unlocked and free-running.

Now assume now that the output wavelength of the master laser is set to λ₁ giving the larger wavelength difference between the master laser and the slave laser. This corresponds to an upward shift of the switch thresholds P_{TE-TM} and P_{TM-TE} upwards as shown in the figure. In contrast to the situation above, the reflection from the intermediate reflectivity marks (marks 4-7 and 16-17) is no longer sufficient to achieve locking of the slave laser. Therefore, the intermediate reflectivity marks are interpreted as binary zeros. In other words, the injected power resulting from reflection from these intermediate reflectivity marks is lower than the threshold P_{TM-TE,} which has now shifted to higher values than in the previous situation since the wavelength difference between the two lasers is larger, thus leaving the slave laser free-running.

Although the description has been given with reference to two different wavelengths for the master laser, it is of course obvious to implement the present invention for more wavelengths. Therefore, the present invention provides an arrangement for reading multilevel recordings having a plurality of gray-levels.

Tuning of the output wavelength of the master laser has in the description above been achieved by means of a feedback grating. However, tuning could also be achieved through the electrical control of the master laser, by tunable gratings coupled to the master laser, or by any other suitable means. Notably, the present invention is not limited to some particular way of tuning the output wavelength of the master laser.

In conclusion, the present invention provides improved and simplified read-out of information from an optical information carrier, in particular in connection with multi-level storage. The invention is based on the use of an optical flip-flop, the sensitivity of which is controlled by means of the emission wavelength from a master laser as compared to the free-running emission wavelength from a slave laser. Read-out of information is performed by monitoring the state of the optical flip-flop, which is the locked/unlocked state of the slave laser in this typically case.

1. An arrangement for optical read-out of information stored on an optical information carrier (30), comprising:
a master laser (10);
a slave laser (20);
an optical system which is arranged to direct light from the master laser onto the optical information carrier, to receive light reflected from the information carrier, and thereupon to inject the reflected light into the slave laser; and
control means for adjusting the emission wavelength of the master laser and thereby controlling the wavelength difference between the emission from master laser and a free-running emission from the slave laser.

2. An arrangement as claimed in claim 1, wherein the optical system is arranged to inject light from the master laser into the slave laser in such manner that the polarization state of the injected light is generally orthogonal to a free-running polarization of the slave laser.

3. An arrangement as claimed in claim 1, wherein the emission wavelength of the master laser is determined by means of a feedback grating (11).

4. An arrangement as claimed in claim 3, wherein the control means for adjusting the emission wavelength of the master laser is arranged to adjust the position of said grating (11).

5. An arrangement as claimed in claim 1, wherein the control means is operative to toggle the emission wavelength of the master laser between at least two different wavelengths.

6. A method of reading information from an optical information carrier (30), wherein the information is stored in the form of marks of at least two different reflectivities, the method comprising the steps of:
directing light from a master laser (10) onto said information carrier;
receiving reflected light from said information carrier;
injecting said reflected light into a slave laser (20); and
adjusting the emission wavelength of the master laser in order to control the wavelength difference between the master laser and a free-running slave laser, to thereby adjust read-out sensitivity.

7. A method according to claim 6, wherein the light from the master laser is injected into the slave laser in a polarization state that is generally orthogonal to the free-running polarization of the slave laser

8. An optical drive comprising an arrangement as claimed in claim 1.
